(19) United States
(12) Patent Application Publication
(10) Pub. No.: US 2006/0069969 A1
(43) Pub. Date: Mar. 30, 2006

(54) Inversion based stimulus generation for device testing

(75) Inventors: Sebastian Ohnewald, Dresden (DE); Eric Swartzendruber, Round Rock, TX (US); Kai Eichhorn, Callenberg (DE)

Correspondence Address: MEYERTONS, HOOD, KIVLIN, KOWERT & GOETZEL, P.C., P.O. BOX 398, AUSTIN, TX, 78767-0398, US

(73) Assignee: Advanced Micro Devices, Inc.

(21) Appl. No.: 11/011,397

(22) Filed: Dec. 14, 2004

(30) Foreign Application Priority Data
Sep. 30, 2004 (DE) 10 2004 047 633.0

(51) Int. Cl. G01R 31/28

(52) U.S. Cl. 714/724

(57) ABSTRACT

A device testing apparatus and method for testing a semiconductor device is provided. For device testing, stimulus data is generated and provided to the semiconductor device, and output data of the semiconductor device is then evaluated to verify proper operation of the semiconductor device. Further, data in the semiconductor device output data space is mapped to stimulus data, and a set of stimulus data is determined based on the mapping results for further testing.

### BACKGROUND OF THE INVENTION

1. Field of the Invention

The invention generally relates to semiconductor device testing systems, and more particularly to the generation of stimulus data that is to be provided to the semiconductor device.

2. Description of the Related Art

Semiconductor devices are usually subjected to extensive testing and verification in a manufacturing environment to ensure proper operation of the device. As with continuously increasing circuit depths in highly integrated electronic systems and chips the complexity of digital circuitry to be tested increases as well, functional verification is often found to be the bottleneck in the entire manufacturing process. For this reason, automated testing systems have been developed to automate the process of testing manufactured devices.

FIG. 1 illustrates the components of a conventional automated system 110 that is connected to the device (or design) under test (DUT) 100. The testing system 110 has a stimulus generator 120 to generate stimuli and apply them to the device 100. In response to the stimuli, the device 100 generates output data which is provided to the result evaluator 130 of the testing system 110. The result evaluator 130 evaluates the output data to verify proper operation of the device 100, or to isolate failures in operation.

For evaluating the output data, the result evaluator 130 of the testing system 110 has access to some reference data. These reference data may already be present in the result evaluator 130 itself, or may be provided from the stimulus generator 120 or some reference system inside or outside the testing system 110. In general, the result evaluator 130 performs a comparison between the output data of the device 100 and the reference data to verify proper operation of the device 100.

Conventional testing tools use either specific, predefined stimulus patterns or offer general random stimulus data generation. The deterministic approach is good to perform specific testing of individual functionality. In contrast thereto, the random approach allows for broadly testing a device in all of its functionality aspects without requiring to initially specify these aspects. However, the verification of a device under test can end up in a time-consuming process.

A number of strategies are known to make testing more versatile. For instance, tests for functional verification can be generated in a constraint-driven manner. Further, functional analysis may automatically identify holes in the test coverage. Another conventional approach is to generate the random stimulus data with different random distributions. Other strategies allow for performing a directed random test as a group of random tests that attempt to cover an area of the test space by constraining the randomness to a range of values. Directed tests are normally fully specified, but may also allow for constraining the randomness of test parameters. Nevertheless, random tests are not at all specific.

Another conventional verification approach is coverage driven verification. Once a verification plan is defined, a coverage model is defined that uses both functional coverage and code coverage. Functional coverage is used as primary measurement technique, and code coverage results are then analyzed to catch omissions in the functional coverage model.

Yet another approach is intent-driven verification to detect differences between what the designer intends to build and the structure described within the designer's source code. The methodology includes an (expressed or implied) intent capture phase, an intent gap detection phase, and an intent violation phase. Using this technique, the stimulus coverage can be maximized for a given design. For doing so, an exhaustive analysis of all possible input combinations is performed and the results are ensured to hold true for all design stimuli.

All of these conventional techniques do actually not completely solve the bottleneck problem. That is, device testing (including simulation and verification) is often still found to be inefficient because of the significant amount of time consumed by the process. On the other hand, if testing is stopped too early, the test results are no longer reliable and lack accuracy.

### SUMMARY OF THE INVENTION

A device testing apparatus and method are provided that may improve efficiency, reliability and accuracy.

In one embodiment, a device testing apparatus is provided for testing a semiconductor device. The apparatus comprises a stimulus generator that is adapted to generate stimulus data to be provided to the semiconductor device. The apparatus further comprises a result evaluator that is connected to receive output data from the semiconductor device in response to generated stimulus data that is provided to the semiconductor device, wherein the result evaluator is adapted to evaluate the output data to verify proper operation of the semiconductor device. The apparatus further comprises a backmapping unit that is adapted to map data in the semiconductor device output data space to stimulus data and determine a set of stimulus data for further testing.

In another embodiment, there is provided a device testing method for testing a semiconductor device. The method comprises generating stimulus data, providing the generated stimulus data to the semiconductor device, and evaluating output data of the semiconductor device to verify proper operation of the semiconductor device. The method further comprises mapping data in the semiconductor device output data space to stimulus data and determining a set of stimulus data based on the mapping results for further testing.

According to still a further embodiment, a computer-readable medium has stored thereon instructions that, when executed by a processor, cause the processor to test a semiconductor device by mapping data in the semiconductor device output data space back to stimulus data, and determining a reduced set of stimulus data for further testing.

### BRIEF DESCRIPTION OF THE DRAWINGS

The accompanying drawings are incorporated into and form a part of the specification for the purpose of explaining the principles of the invention. The drawings are not to be construed as limiting the invention to only the illustrated and described examples of how the invention can be made and used. Further features and advantages will become apparent from the following and more particular description of the invention, as illustrated in the accompanying drawings, wherein:

FIG. 1 is a block diagram illustrating a conventional device testing system;

FIG. 2 is a block diagram illustrating a device testing apparatus according to an embodiment, coupled to a semiconductor device;

FIG. 3 is a sketch scheme illustrating the mapping approach of an embodiment;

FIG. 4 is a flow chart illustrating a device testing process according to an embodiment;

FIG. 5 is a sketch scheme illustrating the mapping approach of another embodiment;

FIG. 6 is a flow chart illustrating a device testing process according to another embodiment;

FIG. 7 is a block diagram illustrating an example of a mapping function that can be used in an embodiment;

FIG. 8 is a block diagram illustrating a backmapping function that corresponds to the mapping function of FIG. 7;

FIG. 9 is a block diagram illustrating another example of a mapping function that can be used in an embodiment; and

FIG. 10 is a block diagram illustrating a backmapping function that corresponds to the mapping function of FIG. 9.

### DETAILED DESCRIPTION OF THE INVENTION

The illustrative embodiments of the present invention will be described with reference to the figure drawings wherein like elements and structures are indicated by like reference numbers.

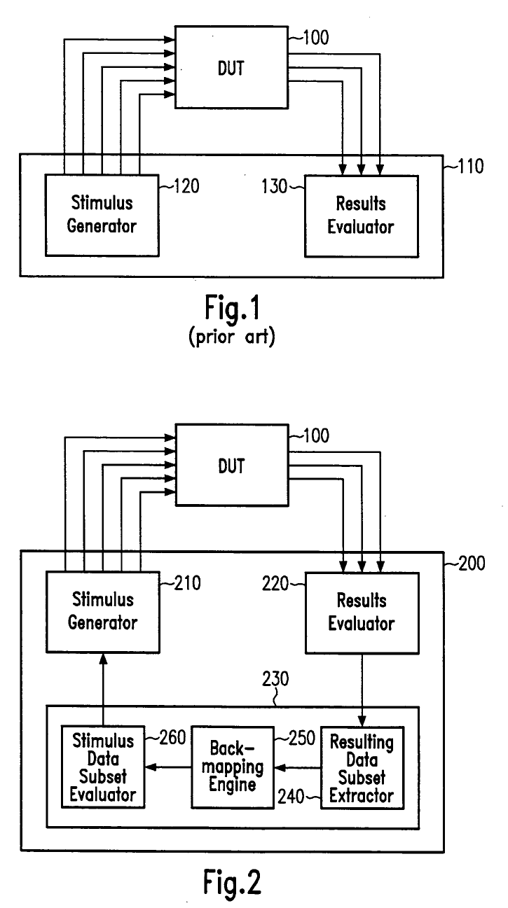

Referring now to the figures, and in particular to FIG. 2, a device testing apparatus 200 according to an embodiment is shown. The device testing apparatus is connected to a semiconductor device 100. To test the device 100, a stimulus generator 210 of the device testing apparatus 200 provides stimulus data to the device 100, and a result evaluator 220 of the device testing apparatus 200 receives output data from the device 100. The result evaluator 220 evaluates the output data to determine whether the semiconductor device 100 properly operates. As described above with reference to FIG. 1 the evaluation by the result evaluator 220 may be based on (internal or external) reference data.

In the present embodiment, the semiconductor device 100 is a digital integrated circuit chip. In another embodiment, the semiconductor device 100 may be one or more individual, potentially separate circuits on a chip. In further embodiments, the semiconductor device 100 may include analog circuits which may also be tested.

The stimulus data generated by the stimulus generator 210 may be provided to the semiconductor device 100 as digital waveforms. In other embodiments, any other kind of stimulus signals may be used to communicate the generated stimuli to the semiconductor device 100.

As apparent from FIG. 2, the device testing apparatus 200 further comprises a feedback unit 230 that is connected to the result evaluator 220 to receive device output data or other data describing the test results. The feedback unit 230 is further connected to the stimulus generator 210 to control the generation of the stimuli. This will be described in more detail below.

It is to be noted that in other embodiments, the feedback unit 230 may be located inside the result evaluator 220 or inside the stimulus generator 210. In further embodiments, some parts of the feedback unit 230 may be realized inside or outside one or more of the other components.

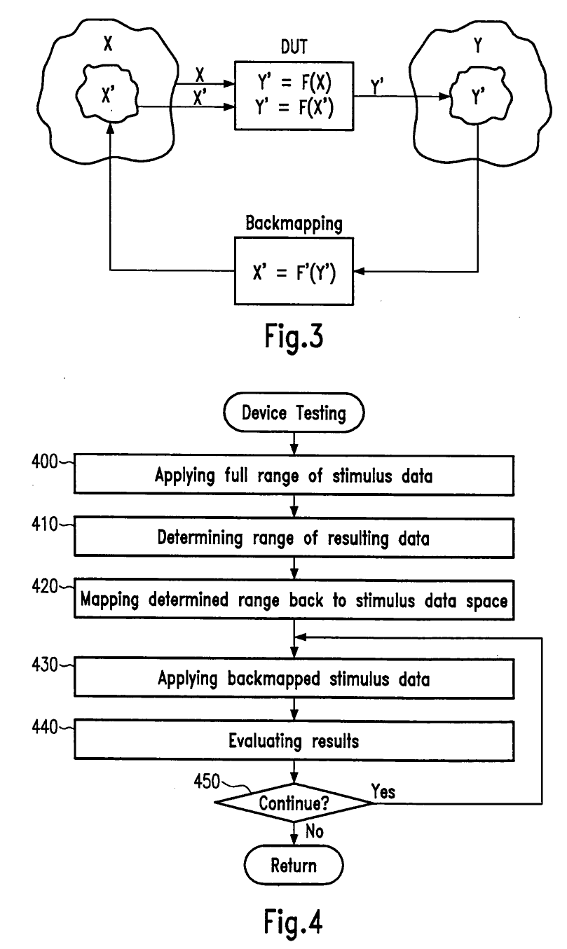

As shown in FIG. 2, the feedback unit 230 comprises a resulting data subset extractor 240, a backmapping engine 250, and a stimulus data subset evaluator 260. The resulting data subset extractor 240 acts as a result data set determination unit and determines a set (or subset) of semiconductor device output data in the available result data space. As will be apparent from the more detailed description below with reference to FIG. 3, the embodiments make use of the fact that semiconductor devices 100 usually do not produce output data in the entire result data space. Thus, unit 240 evaluates in which part of the result data space the output data are to be found.

This information is then provided to the backmapping engine 250 which maps this subset of semiconductor device output data to the available stimulus data space. The backmapping engine 250 then provides information on that part of the stimulus data space that can be expected to produce valid results, to the stimulus data subset evaluator 260. The stimulus data subset evaluator uses this information to control the stimulus generator 210 to generate stimulus data in accordance with that part of the available stimulus data space where the set of semiconductor device output data was mapped to.

Thus, the embodiments avoid generating stimulus data that can be expected not to produce valid results. This expectation is based on a feedback from the used parts of the result data space to the stimulus data space.

Turning now to FIG. 3, the feedback approach according to the embodiments is depicted in more detail. On the left-hand side of the figure, X represents the set of possible stimulus data, i.e. the available stimulus data space. Data within this data space is then provided to the device, and the device outputs result data Y′. As apparent from the right-hand side of the figure, the output data Y′ may be located in a part of the entire result data space Y.

When describing the behavior of the semiconductor device by a function F, the mapping by the semiconductor device of the stimulus data set X to the resulting data set Y′ may be described as Y′=F(X). A reverse function F′ (or F⁻¹) of the mapping function F may then be used in the feedback. That is, the actually used part Y′ of the result data space Y is used as input to the reverse function F′ to determine that part X′ of the available stimulus data space X which may lead to output data within Y′. The feedback may then be represented by a backmapping according to X′=F′(Y′).

Once the reduced stimulus data space X′ is determined, stimulus data in this range can be produced and used for testing. The operation of the semiconductor device may then be described by Y′=F(X′). Thus, it is avoided to generate stimulus data that is found in X but not in X′. By focusing on the actually used part of the data spaces, the time efforts for simulation/verification can be significantly reduced, thereby improving efficiency, reliability and accuracy.

It is further to be noted that those embodiments which use the reverse function F′ of the device's mapping function F for providing the feedback make consequent use of information on the behavior of the semiconductor device. This is because the reverse function F′ may differ from device to device. It is further to be noted that even for one device, more than one mapping function F may be used depending on the specific application tested. As this may then also lead to different reverse functions F′ for different applications, the embodiments may provide application specific stimulus generation, thereby improving the overall efficiency of the entire testing system even more.

Referring to the backmapping, it should be noted that any kind of method for backmapping can be applied, such as any scheme for backwards transformation or inverse modeling.

The result data subset Y′ may be a set of semiconductor device output data. This set may be one or more of the following: a certain data value within the data space Y, a set of certain data values, a certain range of data values, and a certain distribution of values. It should be noted that Y and Y′ may be multi-dimensional, and the dimension of Y′ may be different from the dimension of Y. Further, there may be exceptions in the data space, e.g., overflows. It is further to be noted that Y′ may be a compact set in one embodiment, but may also include a number of separate parts of the data space.

Turning now to FIG. 4, an exemplary device testing process is shown according to an embodiment. In step 400, the full range of stimulus data is applied to the semiconductor device 100. In an embodiment, the range of stimulus data applied in step 400 is determined based on reference data provided from an internal or external reference system.

In step 410, the range Y′ of resulting data is determined. This range is then mapped back to the stimulus data space in step 420 to determine X′. Following this initial testing phase, an iterative procedure is performed to effectively test the device. In each iteration, stimulus data within the backmapped data space is applied to the device in step 430, and the results are evaluated to verify proper operation of the device (step 440). It is then determined in step 450 whether the iteration is to be continued.

While the above embodiments are described to control the stimulus generator in a first device testing phase to generate unrestricted stimulus data and in a second phase to generate stimulus data only within X′, it should be noted that other embodiments exist which do not make use of the first phase. In these embodiments, information on the subset Y′ is arbitrarily chosen and provided to the system. In these embodiments, Y′ is a subset that can be any desired result data which is in the focus of investigation during simulation/verification one might have. That is, Y′ would then not represent the part of the result data space where the semiconductor device may produce valid output data, but rather any arbitrary subset of interest.

According to yet another embodiment, the backmapping technique can be used to intentionally select a part of the stimulus data space that can be expected to produce invalid results. That is, the feedback is used to determine X′ from Y′ but stimulus data is then generated outside X′ (but within X). In another embodiment, stimulus data may be generated both within and outside X′. It is to be noted that intentionally producing invalid results might be helpful in rubustness and stability tests.

In further embodiments, X′ may be calculated not only by backmapping Y′ using the reverse function F′. Rather, the result of backmapping Y′ may be enhanced by any combination with other X data in the available stimulus data space. This combination may take place with individual arbitrary stimulus data values and/or with any other subset of X. These other subsets may be derived from backmapping other subsets Y′ of the result data space. Moreover, for different subset backmappings, different reverse functions may be used.

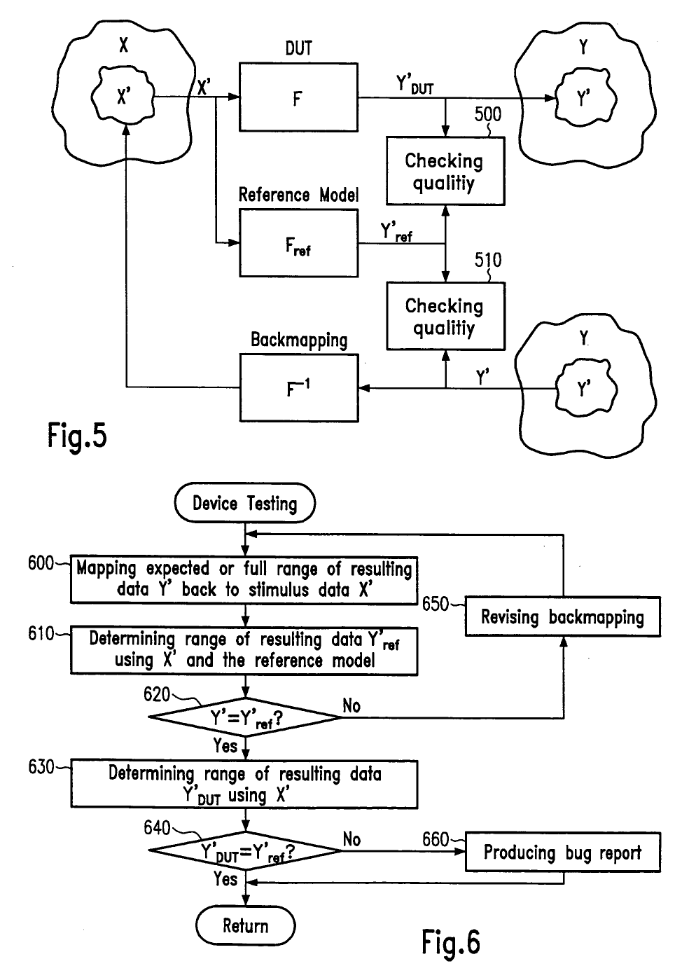

While the above embodiments describe techniques where the semiconductor device output data is fed back via a backmapping routine it is to be noted that further embodiments exist which make use of backmapping without having a direct feedback. One of those embodiments will now be described with reference to FIGS. 5 and 6.

As apparent from FIG. 5, it is not the semiconductor device output data Y′_{DUT} which is used as input to the backmapping, but any desired data set Y′. Nevertheless, the result of backmapping, i.e. the subset X′, is used as input to both the semiconductor device and the reference model. The semiconductor device then produces data according to Y′_{DUT}=F(X′) while the reference model output can be described as Y′_{ref}=F_{ref}(X′). It is to be noted that this embodiment does not require any iteration of method steps.

The quality of the stimulus data and the backmapping procedure may be evaluated in (software or hardware) blocks 500 and 510 by comparing Y′_{ref} with Y′_{DUT} and Y′, respectively. The result of these quality checks may be used to refine the backmapping algorithm. This may or may not be done in an iterative manner.

Referring now to FIG. 6 which is a flowchart illustrating another device testing process according to an embodiment, step 600 applies the expected and/or full range of resulting data Y′ back to stimulus data X′ via the backmapping F′. Then, the range of resulting reference data Y′_{ref} is determined in step 610 using the backmapping result X′ and the reference model funtion F_{ref}. The resulting data Y′ and the reference model output data Y′_{ref} is the compared in step 620 by block 510 to determine whether the backmapping algorithm needs to be refined. If so, the backmapping is revised in step 650, and the process returns to step 600. If not, i.e. Y′ substantially equals Y′_{ref}, the actual device testing may be performed.

For doing so, the range of resulting device data Y′_{DUT} is determined in step 630 using the backmapping result X′. If the semiconductor device output data Y′_{DUT} substantially equals Y′_{ref}, the semiconductor device may be assumed to properly operate, and device testing may be continued. If there is, however, a discrepancy between Y′_{DUT} and Y′_{ref}, a bug report may be produced in step 660. The testing may then be continued to find further bugs, or may be interrupted. Notably, the embodiment of FIG. 6 does not perform an iteration in steps 630, 640 and 660.

In any of the above embodiments, the mapping and backmapping functions F, F′ may be based on the functional algorithmic description of the semiconductor device as specified in the device development and manufacturing phase. The backmapping function F′ is then specified as reverse function of the mapping function F. This may be done by using a mathematically reverse functional definition, or by arranging hardware and/or software components in a reverse order and using complementary components, to achieve the same or similar result.

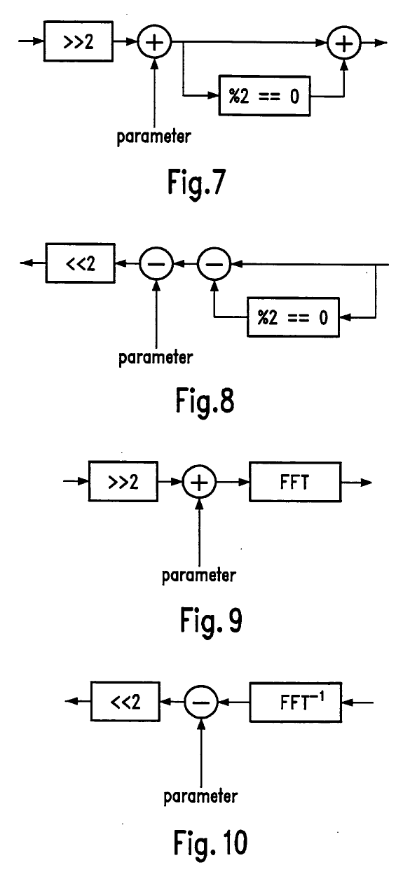

An example of a mapping and a backmapping function is shown in FIGS. 7 and 8, respectively. Apparently, the order of the components is reversed, and components are exchanged with complementary components, such as adders with subtractors and shifters with backshifters. It is noted that in the present embodiment, input parameters of both the mapping and backmapping functions are the same. However, in further embodiments, input parameters of the mapping function may be inverted when being applied to the backmapping function.

Another example of a mapping and a backmapping function is shown in FIGS. 9 and 10, respectively. In this embodiment, a Fast Fourier Transformation (FFT) and its reverse transformation is used.

Given the above described embodiments, it is to be noted that an improvement over conventional techniques is provided since the embodiments are not limited to the use of an inversion of logical behaviour. Rather, forming the inverse of a reference model is not limited to logical coverage metrics.

While the invention has been described with respect to the physical embodiments constructed in accordance therewith, it will be apparent to those skilled in the art that various modifications, variations and improvements of the present invention may be made in the light of the above teachings and within the purview of the appended claims without departing from the spirit and intended scope of the invention. For instance, any feature described in the context of one specific embodiment may likewise be provided in any other of the embodiments.

In addition, those areas in which it is believed that those of ordinary skill in the art are familiar, have not been described herein in order to not unnecessarily obscure the invention described herein. Accordingly, it is to be understood that the invention is not to be limited by the specific illustrative embodiments, but only by the scope of the appended claims.

What is claimed is:

1. A device testing apparatus for testing a semiconductor device, comprising:
a stimulus generator adapted to generate stimulus data to be provided to said semiconductor device; and
a result evaluator connected to receive output data from said semiconductor device in response to generated stimulus data being provided to said semiconductor device, said result evaluator being adapted to evaluate said output data to verify proper operation of said semiconductor device,
wherein said device testing apparatus further comprises a backmapping unit adapted to map data in the semiconductor device output data space to stimulus data and determine a set of stimulus data for further testing.

2. The device testing apparatus of claim 1, wherein said backmapping unit is comprised in a feedback unit of said device testing apparatus, and said data in the semiconductor device output data space is semiconductor device output data.

3. The device testing apparatus of claim 1, wherein said stimulus generator is further capable of restricting generation of stimulus data to the determined set of stimulus data.

4. The device testing apparatus of claim 3, wherein said stimulus generator is further capable of combining further stimulus data into said set of stimulus data.

5. The device testing apparatus of claim 3, wherein said stimulus generator is further capable of combining another set of stimulus data into the determined set of stimulus data.

6. The device testing apparatus of claim 1, wherein the mapped data is one of the following: an individual data item representing an individual data value, a set of individual data items each representing an individual data value, data within a specific range of data values, and a specific distribution of data values.

7. The device testing apparatus of claim 1, wherein said backmapping unit is adapted to take into account exceptions in the data path.

8. The device testing apparatus of claim 1, wherein said backmapping unit is adapted to map said data in the semiconductor device output data space to stimulus data by generating a functional description of said data and applying a backmapping function to said functional description to obtain a functional description of stimulus data,
wherein said backmapping unit is further adapted to determine said set of stimulus data for further testing by determining stimulus data items complying with the obtained functional description of stimulus data.

9. The device testing apparatus of claim 8, wherein said backmapping function is a reverse function of a mapping function approximately describing the behaviour of said semiconductor device.

10. The device testing apparatus of claim 8, wherein said backmapping function is a selected one of a plurality of predefined functions.

11. The device testing apparatus of claim 8, wherein said backmapping function is adapted to said semiconductor device by adjusting at least one functional parameter.

12. The device testing apparatus of claim 1, wherein:
the device testing apparatus further comprises a result data set determination unit adapted to determine a set of semiconductor device output data in the available result data space;
said backmapping unit is adapted to map said set of semiconductor device output data to the available stimulus data space; and
the device testing apparatus further comprises a stimulus data set evaluator adapted to control said stimulus generator to generate stimulus data in accordance with that part of the available stimulus data space where said set of semiconductor device output data was mapped to.

13. The device testing apparatus of claim 1, wherein said stimulus generator is controlled in a first device testing phase to generate unrestricted stimulus data, and in a second device testing phase following a data mapping process in said backmapping unit, to generate stimulus data only within said set of stimulus data.

14. The device testing apparatus of claim 1, wherein said backmapping unit is adapted to determine said set of stimulus data for further testing so as to cause said semiconductor device to produce invalid output data.

15. The device testing apparatus of claim 1, wherein said stimulus generator is controlled to generate stimulus data for further testing outside said set of stimulus data.

16. The device testing apparatus of claim 1, wherein said backmapping unit is operated in a first phase to map data in the semiconductor device output data space to stimulus data and determine a set of stimulus data for further testing, and device testing is performed in a second phase using the determined stimulus data.

17. The device testing apparatus of claim 16, wherein an iterative refinement procedure is performed in the first phase to optimize data backmapping.

18. The device testing apparatus of claim 17, wherein device testing is performed in the second phase in a non-iterative manner.

19. The device testing apparatus of claim 1, wherein said data in the semiconductor device output data space is predefined.

20. A device testing method for testing a semiconductor device, comprising:
generating stimulus data;
providing the generated stimulus data to said semiconductor device; and
evaluating output data of said semiconductor device to verify proper operation of said semiconductor device,
wherein the method further comprises:
mapping data in the semiconductor device output data space to stimulus data; and
determining a set of stimulus data based on the mapping results for further testing.

21. The device testing method of claim 20, wherein said data in the semiconductor device output data space is semiconductor device output data.

22. The device testing method of claim 20, wherein generating stimulus data comprises:
restricting the range of possible stimulus data to said set of stimulus data.

23. The device testing method of claim 22, wherein generating stimulus data comprises:
combining further stimulus data into said set of stimulus data.

24. The device testing method of claim 22, wherein generating stimulus data comprises:
combining another set of stimulus data into the determined set of stimulus data.

25. The device testing method of claim 20, wherein the mapped data is one of the following: an individual data item representing an individual data value, a set of individual data items each representing an individual data value, data within a specific range of data values, and a specific distribution of data values.

26. The device testing method of claim 20, wherein the mapping is adapted to take into account exceptions in the data path to and/or from said semiconductor device.

27. The device testing method of claim 20, wherein mapping data in the semiconductor device output data space to stimulus data comprises:
generating a functional description of the data; and
applying a backmapping function to said functional description to obtain a functional description of stimulus data,
wherein determining a set of stimulus data for further testing comprises:
determining stimulus data items complying with the obtained functional description of stimulus data.

28. The device testing method of claim 27, wherein said backmapping function is a reverse function of a mapping function approximately describing the behaviour of said semiconductor device.

29. The device testing method of claim 27, wherein said backmapping function is a selected one of a plurality of predefined functions.

30. The device testing method of claim 27, wherein said backmapping function is adapted to said semiconductor device by adjusting at least one functional parameter.

31. The device testing method of claim 20, wherein mapping data in the semiconductor device output data space to stimulus data comprises:
determining a set of data in the available result data space;
mapping said set of data to the available stimulus data space; and
controlling generation of stimulus data in accordance with that part of the available stimulus data space where said set of data was mapped to.

32. The device testing method of claim 20, wherein stimulus data generation is controlled in a first device testing phase to generate unrestricted stimulus data, and in a second device testing phase following a data mapping process, to generate stimulus data only within said set of stimulus data.

33. The device testing method of claim 20, wherein said set of stimulus data is determined so as to cause said semiconductor device to produce invalid output data.

34. The device testing method of claim 20, wherein said stimulus data is generated for further testing outside said set of stimulus data.

35. The device testing method of claim 20, wherein mapping data in the semiconductor device output data space to stimulus data and determining a set of stimulus data is performed in a first phase, and device testing is performed in a second phase using the determined stimulus data.

36. The device testing method of claim 35, wherein an iterative refinement procedure is performed in the first phase to optimize data said mapping data in the semiconductor device output data space to stimulus data.

37. The device testing method of claim 36, wherein device testing is performed in the second phase in a non-iterative manner.

38. The device testing method of claim 20, wherein said data in the semiconductor device output data space is predefined.

39. A computer-readable medium having stored thereon instructions that when executed by a processor cause the processor to test a semiconductor device by mapping data in the semiconductor device output data space back to stimulus data, and determining a reduced set of stimulus data for further testing.
